(19) United States
(12) Patent Application Publication
(10) Pub. No.: US 2024/0413244 A1
(43) Pub. Date: Dec. 12, 2024

(54) DIELECTRIC FEATURES FOR PARASITIC CAPACITANCE REDUCTION

(71) Applicant: Taiwan Semiconductor Manufacturing Company, Ltd., Hsinchu (TW)

(72) Inventors: Wei-Hao Wu, Hsinchu City (TW); Lung Chen, Hsinchu County (TW)

(21) Appl. No.: 18/332,028

(22) Filed: Jun. 9, 2023

(51) Int. Cl. H01L 29/78; H01L 29/417; H01L 29/66

(52) U.S. Cl. CPC H01L 29/785; H01L 29/41775; H01L 29/66545; H01L 29/6656; H01L 29/66795

(57) ABSTRACT

Semiconductor structures and methods of forming the same are provided. An example semiconductor structure includes a fin structure arising from a substrate and extending lengthwise along a direction, an isolation feature over the substrate and around the fin structure, a gate structure wrapping over a channel region of the fin structure, a first gate spacer extending along a sidewall of the gate structure, a second gate spacer over the first gate spacer, a filler dielectric layer over the second gate spacer, an epitaxial feature disposed over a source/drain region of the fin structure, a portion of the epitaxial feature being disposed over the filler dielectric layer, an contact etch stop layer (CESL) over the epitaxial feature and the filler dielectric layer, and an interlayer dielectric (ILD) layer over the CESL. A portion of the CESL extends between the epitaxial feature and the sidewall of gate structure along the direction.

### BACKGROUND

The semiconductor industry has experienced rapid growth. Technological advances in semiconductor materials and design have produced generations of semiconductor devices where each generation has smaller and more complex circuits than the previous generation. In the course of integrated circuit (IC) evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, these advances have also increased the complexity of processing and manufacturing semiconductor devices.

The scaling down of the semiconductor structures reduces distance between conductive features, such as gate structures, source/drain features, and contact features, and presents challenges to reduce parasitic capacitance and increase response time. Various measures have been proposed to reduce parasitic capacitance. Therefore, existing parasitic capacitance reduction measures are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of an example method for fabricating a semiconductor device on a workpiece, according to various embodiments of the present disclosure.

FIGS. 2-23 are fragmentary cross-sectional views and top views of the workpiece in FIG. 1, according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain region(s) may refer to a source or a drain individually or collectively, dependent upon the context.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

As semiconductor devices progress towards smaller technology nodes, closely placed gate structures and source/drain features fuels a continuing quest to reduce parasitic capacitance to improve switching speed and device performance. To lower or minimize parasitic capacitance, insulating (or dielectric) materials with relatively low dielectric constants (k), such as low-k dielectrics and/or air (by forming an air gap, for example), have been explored to insulate conductive structures of a semiconductor device. While low-k dielectrics are desirable in lowering parasitic capacitances, they tend to etch fast and are prone to unintended damages.

The present disclosure provides structures and methods for reducing parasitic capacitance between a gate structure and adjacent source/drain features. In an example process, after a dummy gate stack is formed over a channel region of a fin structure on a substrate, gate spacer layers are conformally deposited over the dummy gate stack and the substrate. A sacrificial dielectric layer is then conformally deposited over the gate spacer layers. The substrate is subjected to an anisotropic etch process to form source/drain recesses over the source/drain regions of the fin structure adjacent the channel region. Source/drain features are formed over the source/drain features. After the formation of the source/drain features, an isotropic etch back process is performed to etch back the sacrificial dielectric layer disposed between the source/drain features and the gate spacer layers extending along sidewalls of the dummy gate stack. After the etching back, a contact etch stop layer (CESL) is deposited over the source/drain features and the etched-back sacrificial dielectric layer. The source/drain features are spaced apart from the gate structure by the sacrificial dielectric layer and the CESL. A dielectric constant of the sacrificial dielectric layer is smaller than a dielectric constant of the CESL.

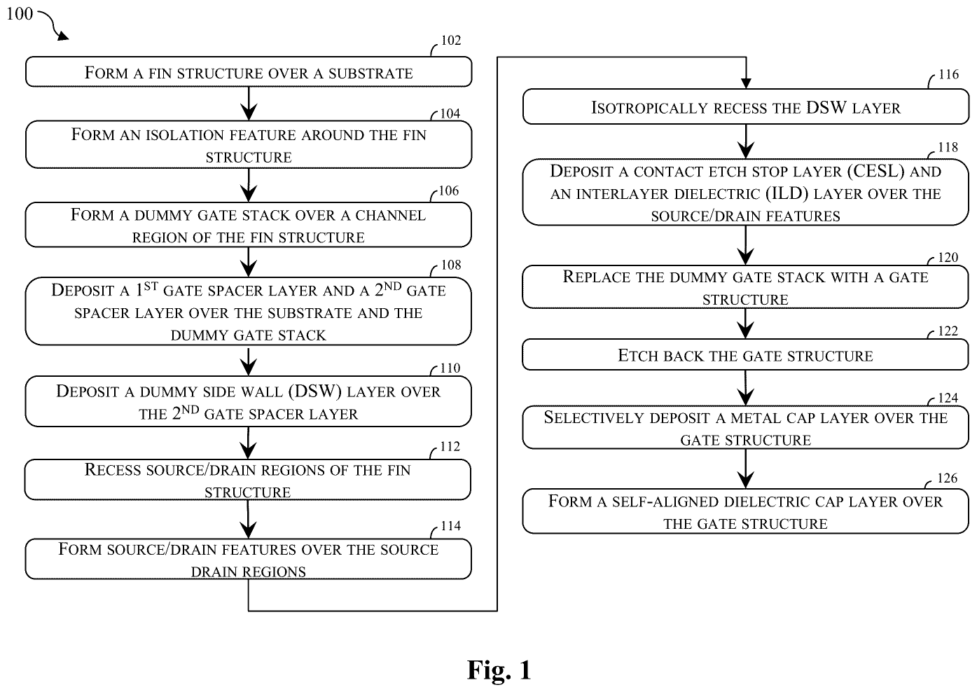

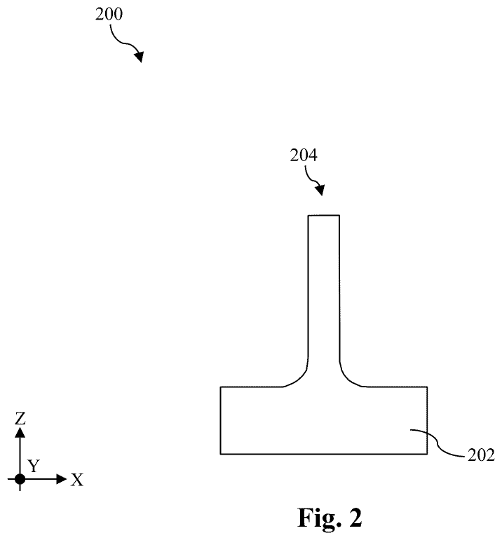

The various aspects of the present disclosure will now be described in more detail with reference to the figures. FIG. 1 illustrates a flowchart of a method 100 of forming a semiconductor structure from a workpiece. Method 100 is merely an example and not intended to limit the present disclosure beyond what is explicitly recited in the claims. Additional operations can be provided before, during, and after method 100, and some operations described can be replaced, eliminated, or moved around for additional embodiments of the method. Method 100 is described below in conjunction with FIGS. 2-23, each of which illustrate a fragmentary cross-sectional view or a top view of the workpiece 200 during various operations of method 100. The workpiece 200 may be an intermediate structure fabricated during fabrication of a semiconductor device or structure. The present disclosure is not limited to any particular number of devices or device regions, or to any particular device configurations. For example, though the workpiece 200 as illustrated includes fin-type field effect transistors (FinFETs), the present disclosure may also be applied to other types of transistors. Additional features can be added in semiconductor devices fabricated on the workpiece 200, and some of the features described below can be replaced, modified, or eliminated in other embodiments of the semiconductor device to be fabricated on the workpiece 200. Because a semiconductor device or a semiconductor structure is to be formed from the workpiece 200 at the conclusion of the processes described in the present disclosure, the workpiece 200 may be referred to as a semiconductor device 200 or a semiconductor structure 200 as the context requires.

Referring FIGS. 1 and 2, method 100 includes a block 102 where a fin structure 204 is formed over a substrate 202. The fin structure 204 is formed over a substrate 202. The substrate 202 may include an elementary (single element) semiconductor, such as silicon (Si), germanium (Ge), and/or other suitable materials; a compound semiconductor (i.e., alloy semiconductor), such as silicon carbide (SiC), gallium arsenic (GaAs), gallium phosphide (GaP), indium phosphide (InP), indium arsenide (InAs), indium antimonide (InSb), silicon germanium (SiGe), gallium arsenic phosphide (GaAsP), aluminum indium arsenide (AllnAs), aluminum gallium arsenide (AlGaAs), gallium indium arsenide (GalnAs), gallium indium phosphide (GalnP), gallium indium phosphide (GalnAsP), and/or other suitable materials. The substrate 202 may be a single-layer material having a uniform composition. Alternatively, the substrate 202 may include multiple material layers having similar or different compositions suitable for IC device manufacturing. In one example, the substrate 202 may be a silicon-on-insulator (SOI) substrate having a silicon layer formed on a buried silicon oxide (BOX) layer. In some embodiments, the substrate 202 includes various doped regions, such as n-type wells or p-type wells. The doped regions may be doped with n-type dopants, such as phosphorus (P) or arsenic (As), and/or p-type dopants, such as boron (B) or BF₂, depending on design requirements. Doped regions may be formed by implantation of dopant atoms, in-situ doped epitaxial growth, and/or other suitable techniques.

To form the fin structure 204 from the substrate 202, a fin-top hard mask layer (not explicitly shown in the figures) may be deposited over the substrate 202. In some embodiments, the fin structure 204 is patterned from the substrate 202 using a combination of lithography and etching processes. For patterning purposes, a hard mask layer may be deposited over the substrate 202. The hard mask layer may be a single layer or a multilayer. In one example, the hard mask layer includes a silicon oxide layer and a silicon nitride layer over the silicon oxide layer. The fin structure 204 may be patterned using suitable processes including double-patterning or multi-patterning processes. Generally, double-patterning or multi-patterning processes combine photolithography and self-aligned processes, allowing patterns to be created that have pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the substrate 202 to form the fin structure 204. The etching process may include dry etching, wet etching, reactive ion etching (RIE), and/or other suitable processes. As shown in FIG. 2, the fin structure 204 arises continuously and vertically from the substrate 202. The fin structure 204 extends lengthwise along the Y direction.

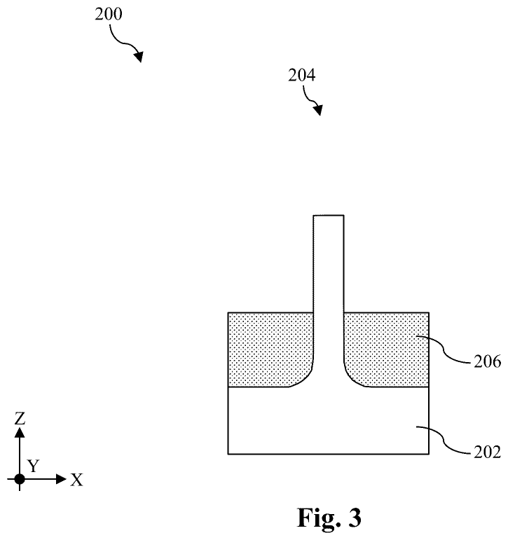

Referring FIGS. 1 and 3, method 100 includes a block 104 where an isolation feature 206 is formed around the fin structure 204. The isolation feature 206, as shown in FIG. 3, isolates the fin structure 204 from another fin structure (omitted for simplicity). In an example process, a dielectric material is first blanketly deposited over the substrate 202 to fill space between the fin structure 204 and another fin structure. The dielectric material may include silicon oxide and may be deposited by chemical vapor deposition (CVD) or a spin-on-glass (SOG) process. A planarization process, such as a CMP process, is then performed. The planarized dielectric material is then selectively etched back to form the isolation feature 206.

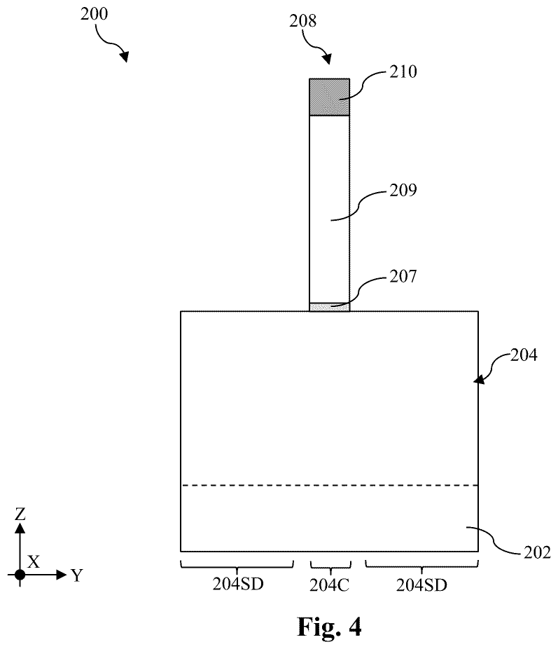

Referring FIGS. 1 and 4, method 100 includes a block 106 where a dummy gate stack 208 over a channel region 204C of the fin structure 204. In the depicted embodiments, a replacement gate process is adopted where dummy gate stacks are formed as placeholders to undergo processes that are harmful to metal gate structures and the dummy gate stacks are later replaced with functional metal gate structures. In the depicted embodiments, the dummy gate stacks formed at block 106 include a dummy gate stack 208 over the channel region 204C of the fin structure 204. In some embodiments, the dummy gate stack 208 includes a dummy gate dielectric layer 207 and a dummy electrode layer 209 over the dummy gate dielectric layer 207. The dummy gate dielectric layer 207 is first formed on the fin structure 204 using thermal oxidation, atomic layer deposition (ALD), or chemical vapor deposition (CVD) and the dummy electrode layer 209 is formed on the dummy gate dielectric layer 207 using CVD. In some embodiments, the dummy gate dielectric layer 207 includes silicon oxide and the dummy electrode layer 209 includes polysilicon.

The deposited dummy gate dielectric layer 207 and dummy electrode layer 209 are then patterned using a combination of photolithography and etching processes. In some implementations, double-patterning or multi-patterning processes may be adopted to pattern the dummy gate stack 208. For purposes of patterning the dummy gate dielectric layer 207 and the dummy electrode layer 209, a gate top hard mask layer 210 is deposited over the dummy electrode layer 209 and patterned. The gate top hard mask layer 210 may be a single layer or a multi-layer and may include silicon oxide or silicon nitride. The patterned gate top hard mask layer 210 is used as an etch mask to etch the underlying dummy gate dielectric layer 207 and the dummy electrode 209 to form the dummy gate stack 208. As shown in FIG. 4, while the fin structure 204 extends lengthwise along the Y direction, the dummy gate stack 208 extends lengthwise along the X direction.

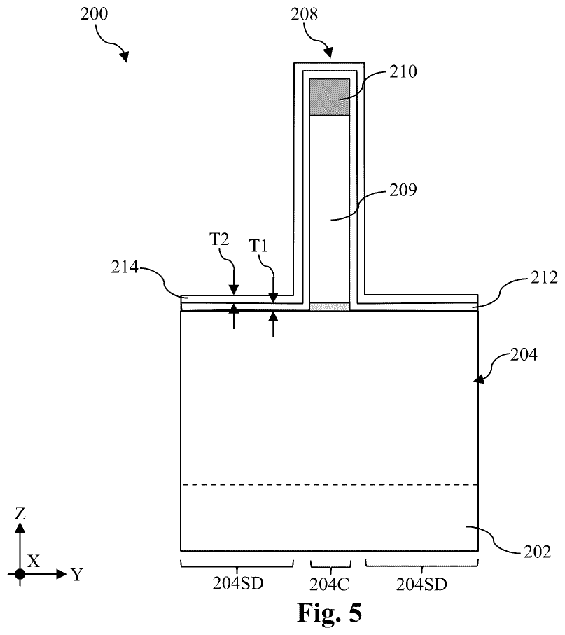

Referring to FIGS. 1 and 5, method 100 includes a block 108 where a first gate spacer layer 212 and a second gate spacer layer 214 are deposited over the substrate 202 and the dummy gate stack 208. In some embodiments represented in the figures, the first gate spacer layer 212 includes silicon oxycarbide (SiOC) or silicon oxycarbonitride (SiCON) and may be conformally deposited along sidewalls of the dummy gate stack 208 and the fin structure 204 using atomic layer deposition (ALD), chemical vapor deposition (CVD), or a suitable conformal deposition method. The first gate spacer layer 212 is intended to etch slower than semiconductor materials and silicon oxide and functions to define and protect the gate structure in a gate replacement process. The second gate spacer layer 214 may also include silicon oxycarbonitride (SiCON) and may be conformally deposited over the first gate spacer layer 212 using ALD, CVD, or a suitable conformal deposition method. Different from the first gate spacer layer 212, the second gate spacer layer 214 has a lower dielectric constant and provide additional distance between the to-be-formed gate structure and the to-be-formed source/drain features. While both the first gate spacer layer 212 and the second gate spacer layer 214 both may include silicon (Si), carbon (C), oxygen, and nitrogen (N), they have different compositions. For example, a carbon content of the first gate spacer layer 212 is greater than a carbon content of the second gate spacer layer 214. In some instances, the carbon content of the first gate spacer layer 212 is at least twice of that of the second gate spacer layer 214. Additionally, the second gate spacer layer 214 includes more oxygen content than the first gate spacer layer 212 for a reduced dielectric constant. As will be described further below, the more silicon-oxide-like second gate spacer layer 214 serves as an etch stop layer (ESL) during the selective removal of a dummy sidewall (DSW) layer 216.

As shown in FIG. 5, the first gate spacer layer 212 has a first thickness T1 and the second gate spacer layer 214 has a second thickness T2. To reduce parasitic capacitance, the second thickness T2 is greater than the first thickness T1, so as to maximize the thickness of the second gate spacer layer 214, which has a smaller dielectric constant than the first gate spacer layer. In some instances, the first thickness T1 may be between about 1.8 nm and about 2.4 nm and the second thickness T2 may be between about 2.4 nm and about 3.2 nm.

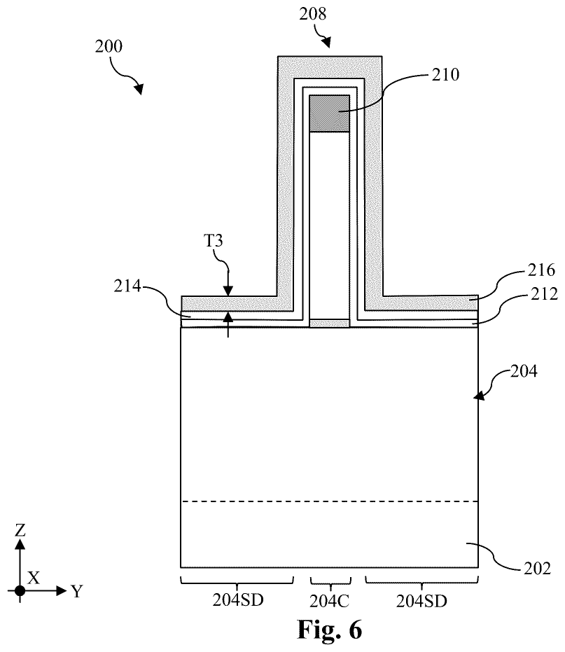

Referring to FIGS. 1 and 6-7, method 100 includes a block 110 where a dummy sidewall (DSW) layer 216 is conformally deposited over the second gate spacer layer 214. Compared to the first gate spacer layer 212 and the second gate spacer layer 214, the DSW layer 216 is more etch-resistant due to its composition and thickness. However, unlike the first gate spacer layer 212 and the second gate spacer layer 214, a substantial portion of the DSW layer 216 is to be removed after it successfully serves its protective function. For that reason, the DSW layer 216 may also be referred to as a sacrificial dielectric layer 216 or a filler dielectric layer 216. In some embodiments, the DSW layer 216 includes silicon oxynitride (SiON) and may be conformally deposited over the second gate spacer layer 214 using ALD, CVD, or a suitable conformal deposition method. To protect the sidewalls of the dummy gate stack 208 during the source/drain recess, the DSW layer 216 has a dielectric constant greater than those of the first gate spacer layer 212 and the second gate spacer layer 214 and has a greater thickness than those of the first gate spacer layer 212 and the second gate spacer layer 214. In some embodiments, the dielectric constant of the DSW layer 216 is between about 6.4 and about 7. As a comparison, a dielectric constant of the first gate spacer layer 212 is between about 4.4 and about 5.1 and a dielectric constant of the second gate spacer layer 214 is between about 3.5 and about 4.4. As shown in FIG. 6, the DSW layer 216 has a third thickness T3, which is greater than the first thickness T1 of the first gate spacer layer 212 or the second thickness T2 of the second gate spacer layer 214. In some instances, the third thickness T3 may be between about 3.3 nm and about 4.4 nm. In terms of etching selectivity, the DSW layer 216 is kept more similar to silicon nitride such that methods that selectively etch silicon nitride can selectively etch the DSW layer 216 without substantially damaging the second gate spacer layer 214.

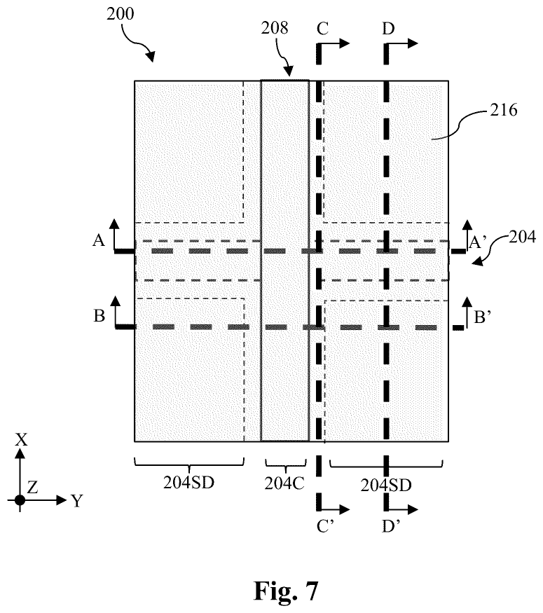

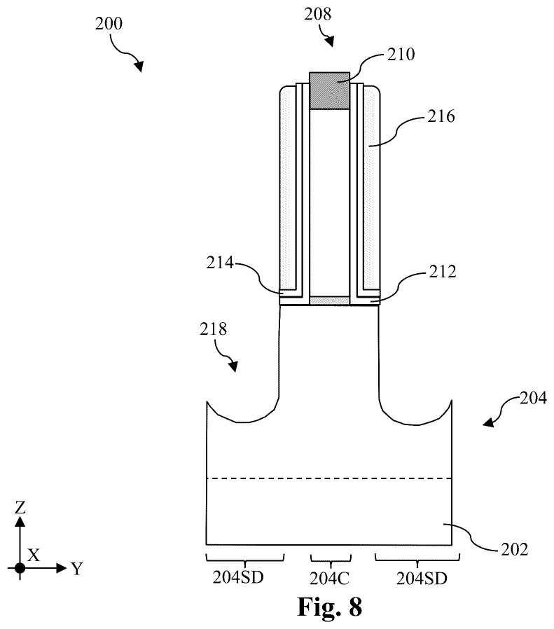

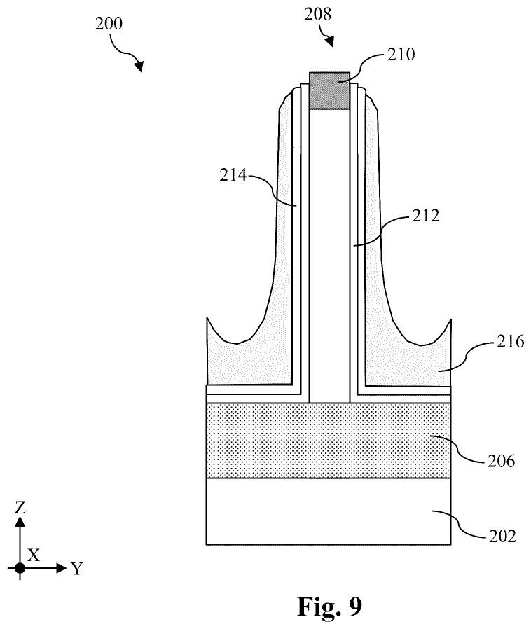

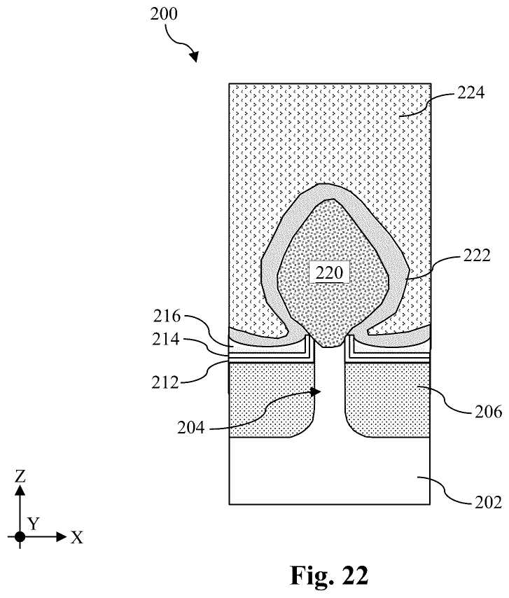

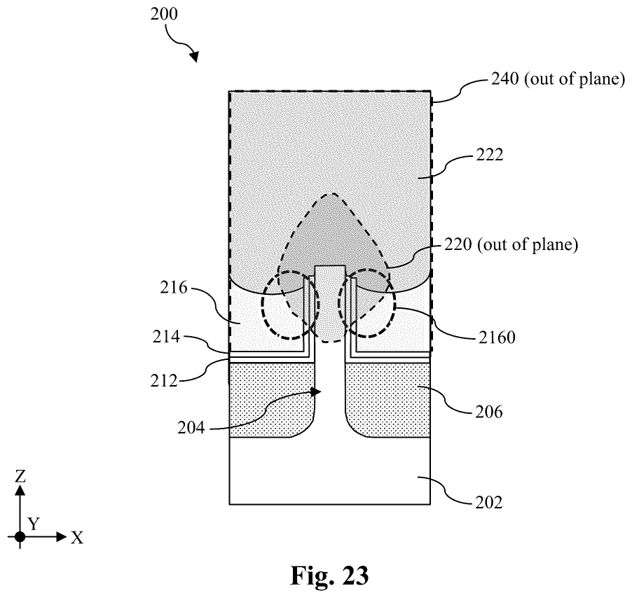

FIG. 7 illustrates a fragmentary top view of the workpiece 200 after the conformal deposition of the DSW layer 216. The fin structure 204 extends lengthwise along the Y direction. The dummy gate stack 208 wraps over the channel region 204C of the fin structure 204 and extends lengthwise along the X direction. In FIG. 7, line A-A′ cuts through the fin structure 204 along its lengthwise direction, line B-B′ cuts through a portion of dummy gate stack 208 that does not overlap the fin structure 204. line C-C′ cuts through the source/drain region 204SD along the X direction, and line D-D′ cuts through a transition region between the channel region 204C and a source/drain region 204SD along the X direction. The fragmentary cross-sectional views in FIGS. 8. 10, 12, 14, 16, 18, and 20 are along line A-A′. The fragmentary cross-sectional views in FIGS. 9, 11, 13, 15, 17, 19, and 21 are along line B-B′. The fragmentary cross-sectional views in FIG. 22 is along line C-C′, albeit after some subsequent processes are performed. The fragmentary cross-sectional views in FIG. 23 is along line D-D′, albeit after some subsequent processes are performed.

Referring to FIGS. 1 and 8-9, method 100 includes a block 112 where source/drain regions 204SD are recessed to form source/drain recesses 218. In some embodiments, the source/drain regions 204SD are anisotropically etched using a dry etch or a suitable etching process to form the source/drain recesses 218. For example, the dry etch process may implement oxygen (O₂), an oxygen-containing gas, a fluorine-containing gas (e.g., CF₄, SF6, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 8, after the formation of the source/drain recesses 218, the first gate spacer layer 212, the second gate spacer layer 214, and the DSW layer 216 may remain disposed along sidewalls of the dummy gate stack 208 over the channel region. Reference is now made to FIG. 9. Because the dry etch process etches the fin structure 204 faster than it etches the DSW layer 216, DSW layer 216 not directly over the fin structure 204 may remain over a top surface of the isolation feature 206. As shown in FIG. 9, the DSW layer 216 is vertically spaced apart from the isolation feature 206 by horizontal portions of the first gate spacer layer 212 and the second gate spacer layer 214.

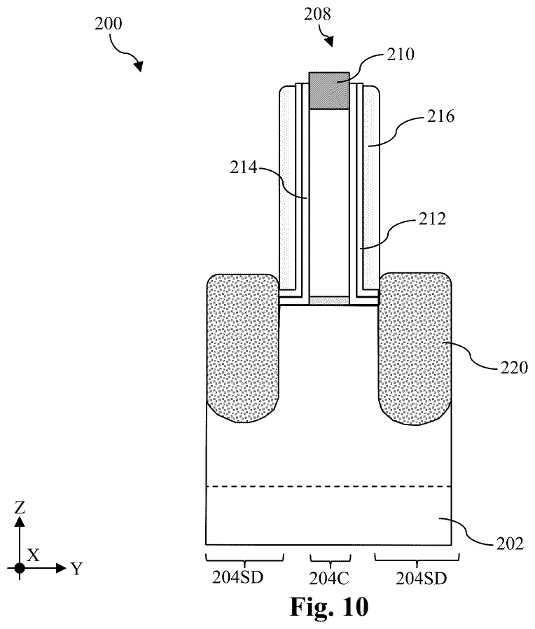

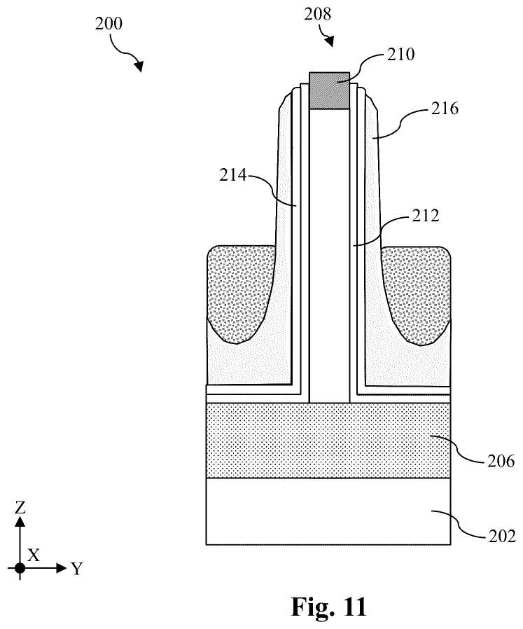

Referring to FIGS. 1 and 10-11, method 100 includes a block 114 where source/drain features 220 are formed over the source/drain regions 204SD. At block 114, source/drain features 220 are formed over the source/drain recess 218 in the source/drain regions 204SD using an epitaxy process. The epitaxy process may implement CVD deposition techniques (for example, vapor-phase epitaxy (VPE), ultra-high vacuum CVD (UHV-CVD), LPCVD, and/or PECVD), molecular beam epitaxy (MBE), other suitable selective epitaxial growth (SEG) processes, or combinations thereof. The source/drain features 220 may be n-type or p-type. When the source/drain features 220 are p-type, they include silicon germanium (SiGe) and a p-type dopants, such boron (B). When the source/drain features 220 are n-type, they include silicon (Si) and an n-type dopants, such as phosphorus (P). Because formation of the source/drain features 220 at block 114 is selective to semiconductor surfaces, the source/drain features 220 grow thicker from exposed semiconductor surfaces in the source/drain recesses 218 shown in FIG. 10. As shown in FIG. 11, overgrowth of the source/drain features 220 along a lateral direction (i.e., X direction) may cause a portion of the source/drain features 220 to span beyond sidewalls of the fin structure 204 to overhang a portion of the DSW layer 216. The overhanging of the source/drain features 220 over the DSW layer 216 is also shown in FIG. 22.

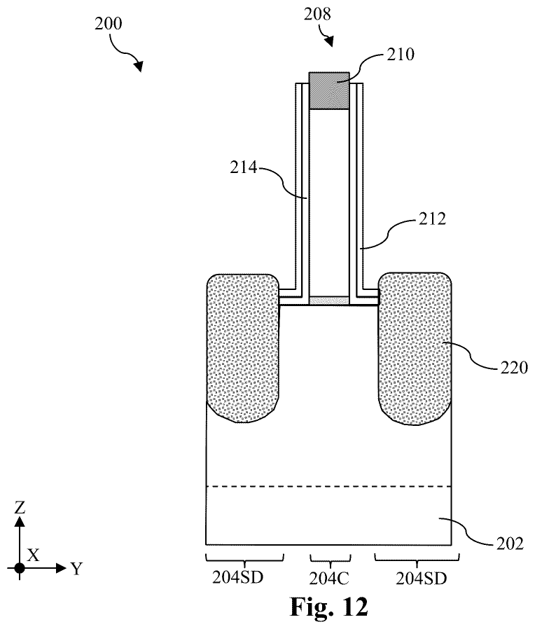

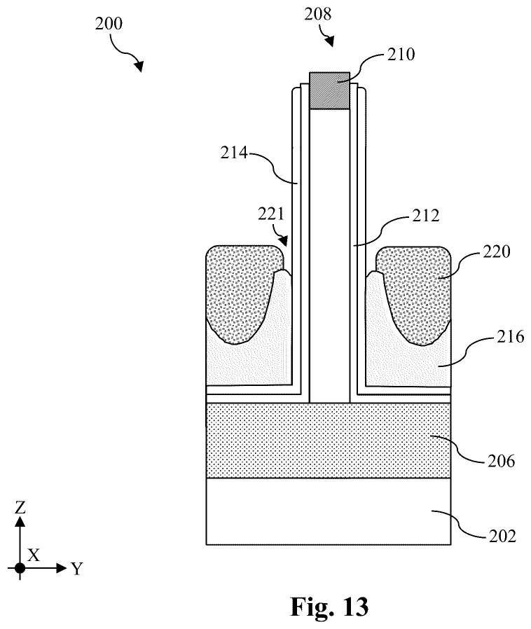

Referring to FIGS. 1 and 12-13, method 100 includes a block 116 where the DSW layer 216 is isotropically etched back. After the recessing of the source/drain regions 204SD at block 112 and the formation of source/drain features 220 at block 114, the DSW layer 216 has served its functions. To reduce the impact of the DSW layer 216 on parasitic capacitance, the DSW layer 216 is selectively etched back. In some embodiments, the etching back of the DSW layer 216 includes use of a hot phosphoric acid solution and a process temperature between 140° C. and about 180° C. As described above, while the DSW 216 may include oxygen, its etching property is kept similar to that of silicon nitride. In these embodiments, the hot phosphoric acid solution, which selectively etches silicon nitride, also selectively etches the DSW layer 216 without causing damages to the second gate spacer layer 214, which is silicon-oxide-like. As shown in FIG. 12, over the channel region 204C, the DSW layer 216 over the second gate spacer layer 214 may be completely removed at block 116. Referring to FIG. 13, the DSW layer 216 is selectively etched back until crevices 221 are formed between the source/drain features 220 and the second gate spacer layer 214 (along sidewalls of the dummy gate stack 208) along the Y direction. That is, along line B-B′ in FIG. 7, a top surface of the DSW layer 216 is lower than top surfaces of the source/drain features 220.

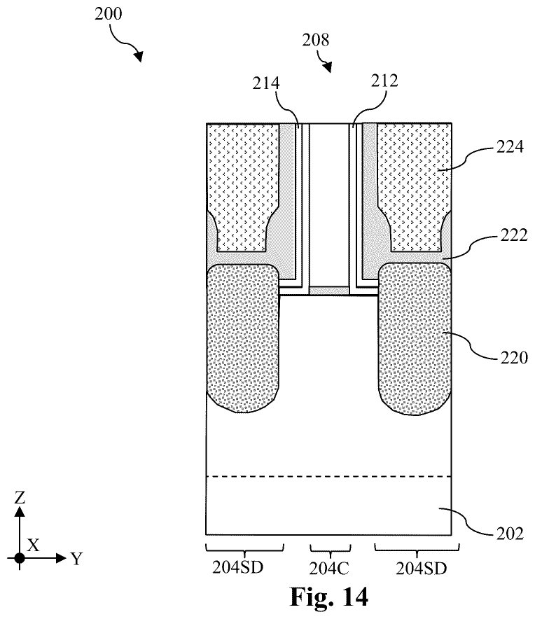

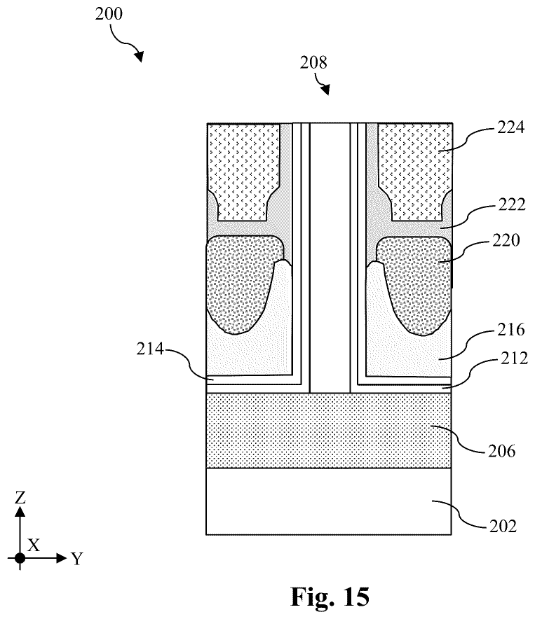

Referring to FIGS. 1 and 14-15, method 100 includes a block 118 where a contact etch stop layer (CESL) 222 and an interlayer dielectric (ILD) layer over the source/drain features 220. As shown in FIGS. 14 and 15, the CESL 222 is formed on the source/drain features 220 and the ILD layer 224 is formed on the CESL 222. The ILD layer 224 is spaced apart from the second gate spacer layer 214, the DSW layer 216, and the sourced/drain features 220 by the CESL 222. In some embodiments, the CESL 222 includes silicon nitride, silicon oxynitride, and/or other materials known in the art. The CESL 222 may be deposited using ALD, plasma-enhanced chemical vapor deposition (PECVD) process and/or other suitable deposition processes. The ILD layer 224 is then deposited over the CESL 222. In some embodiments, the ILD layer 224 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 224 may be deposited by a spin-on process, or other suitable deposition technique. In some embodiments, after formation of the ILD layer 224, the workpiece 200 may be annealed to improve integrity of the ILD layer 224.

Reference is still made to FIGS. 14 and 15. After the deposition of the ILD layer 224, the workpiece 200 is planarized to expose the dummy gate stack 208. At conclusion of the planarization process, top surfaces of the ILD layer 224, the CESL 222, the dummy gate stack 208, the first gate spacer layer 212, and the second gate spacer layer 214 are coplanar. Reference is made to FIG. 15. A portion of the CESL 222 may be deposited into the crevices 221. That is, a portion of the CESL 222 may come between sidewalls of the second gate spacer layer 214 and the source/drain features 220, along the Y direction. The downward extension of the CESL 222 into the crevices 221 serves to protect sidewalls of the source/drain features 220 during formation of source/drain contact openings.

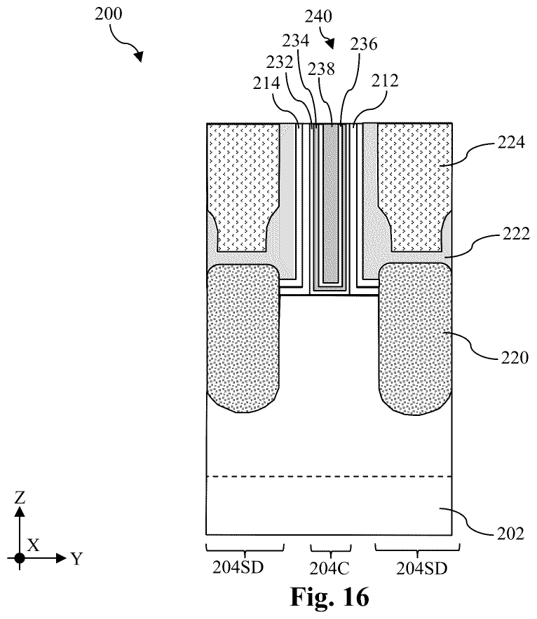

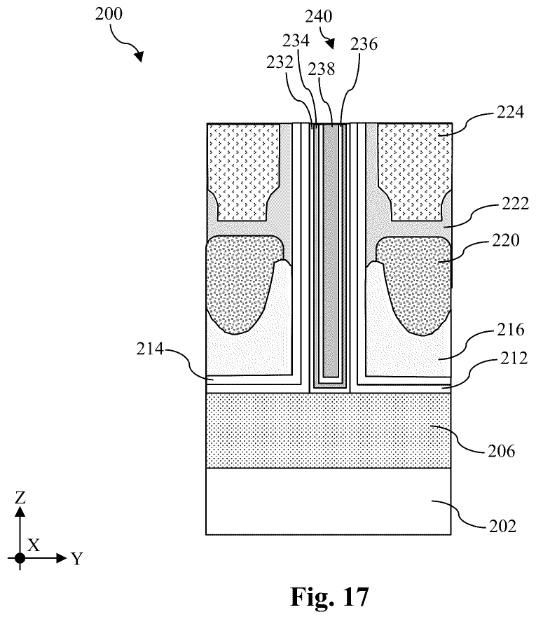

Referring to FIGS. 1 and 16-17, method 100 includes a block 120 where the dummy gate stack 208 is replaced with a gate structure 240. At block 120, gate replacement operations are performed to replace the dummy gate stack 208 (including the dummy gate dielectric layer 207 and the dummy electrode 209) with the gate structure 240. First, the dummy gate stack 208 (including the dummy gate dielectric layer 207 and the dummy electrode 209) is selectively removed to form a gate trench defined by the first gate spacer layer 212. Then, the gate structure is deposited in the gate trench. In some embodiments, the gate structure 240 may include a gate dielectric layer 232, a work function layer 234 over the gate dielectric layer 232, a capping layer 236 over the work function layer 234, and a metal fill layer 238 over the capping layer 236. In some implementations, the gate dielectric layer 232 may include a high-k dielectric layer. The high-k dielectric layer is formed of a dielectric material having a high dielectric constant, for example, greater than a dielectric constant of silicon oxide (k≈3.9). Exemplary high-k dielectric materials include hafnium, aluminum, zirconium, lanthanum, tantalum, titanium, yttrium, oxygen, nitrogen, other suitable constituent, or combinations thereof. In some implementations, the high-k dielectric layer may include, for example, HfO₂, HfSiO, HfSION, HfTaO, HfTIO, HfZrO, ZrO₂, Al₂O₃, HfO₂—Al₂O₃, TiO₂, Ta₂O₅, La₂O₃, Y₂O₃, other suitable high-k dielectric material, or combinations thereof. The work function layer 234 may be a p-type work function layer or an n-type work function layer. When the work function layer 234 is an n-type work function layer, it may include Ti, Al, Ag, Mn, Zr. TiAl, TiAlC, TaC, TaCN, TaSiN, TaAl, TaAlC, TiAlN, other n-type work function material. When the work function layer 234 is a p-work function layer, it may include TiN, TaN, Ru, Mo, Al, WN, ZrSi₂, MoSi₂, TaSi₂. NiSi₂, WN, other p-type work function material, or combinations thereof. The capping layer 236 functions to prevent oxidation of the components in the work function layer 234. The capping layer 236 may include a metal nitride, such as titanium nitride (TiN), tantalum nitride (TaN), tungsten nitride (W₂N), titanium silicon nitride (TiSiN), tantalum silicon nitride (TaSiN), or combinations thereof. The metal fill layer 238 may include a suitable conductive material, such as tungsten (W), ruthenium (Ru), or copper (Cu). The layers in the gate structure 240 may be deposited using physical vapor deposition (PVD) or ALD. After the deposition of the gate structure 240, the workpiece 200 is planarized using, for example, a CMP process to remove excess materials. The gate structure 240 wraps over the channel region 204C as a portion of it lands on a top surface of the gate structure 240 (shown in FIG. 16) and another portion of it extend along sidewalls of the gate structure 240 to land on the isolation feature 206 (shown in FIG. 17). While not explicitly shown in the figures, a silicon oxide interfacial layer may be formed on the top surfaces and sidewalls of the channel region 204C before the deposition of the gate dielectric layer 232. Because the gate structure 240 includes metal and is not formed of polysilicon as the dummy gate stack 208, the gate structure 240 may also be referred to as a metal gate structure 240.

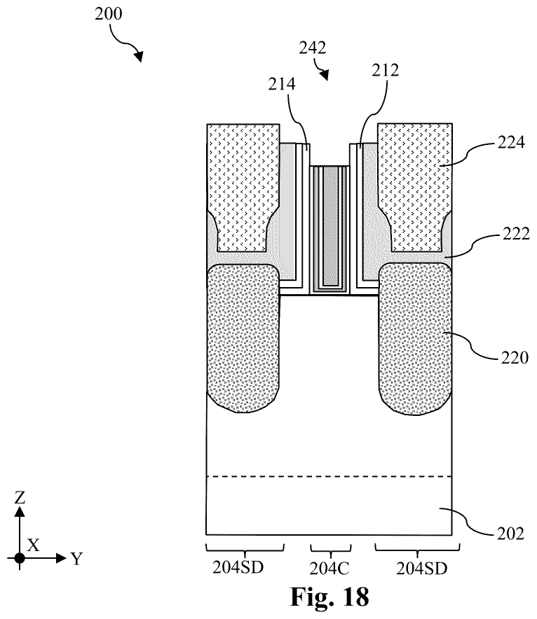

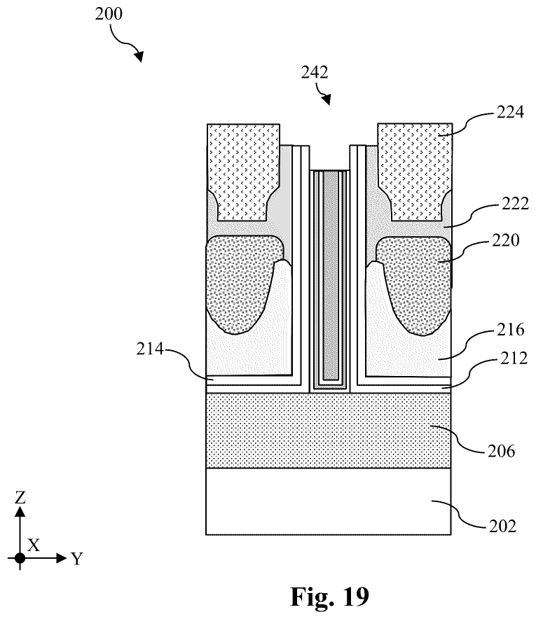

Referring to FIGS. 1 and 18-19, method 100 includes a block 122 where the gate structure 240 is recessed. In some embodiments representatively shown in FIGS. 18 and 19, photolithography and etching processes are implemented at block 122 to selectively recess the gate structure 240, the first gate spacer layer 212, the second gate spacer layer 214, and the CESL 222. For example, a patterned etch mask may be formed over the workpiece 200 to cover the ILD layer 224 while exposing all structures between two adjacent patches of ILD layer 224. The recessing at block 122 may be performed using a dry etch, a wet clean, or a combination thereof. An example dry etch process may include a fluorocarbon (e.g., CF₄, SF₆, NF₃, CH₂F₂, CHF₃, and/or C₂F₆), a chlorine-containing gas (e.g., Cl₂, CHCl₃, CCl₄, and/or BCl₃), oxygen (O₂), hydrogen (H₂), argon (Ar), or a combination thereof. An example wet clean process may include use of ammonium hydroxide (NH₄OH), hydrogen peroxide (H₂O₂), hot deionized water (DI water), isopropyl alcohol (IPA), or ozone (O₃). The recessing at block 122 may form a gate top recess 242. The gate top recess 242 is define between two adjacent patches of the ILD layer 224 along the Y direction and bottom surfaces of the gate top recess 242 are defined by the top surfaces of the CESL 222, the first gate spacer layer 212, the second gate spacer layer 214, and the gate structure 240.

Referring to FIGS. 1 and 20-21, method 100 includes a block 124 where a metal cap layer 244 is selectively deposited over the gate structure 240. In some embodiments, the metal cap layer 244 may include a metal that is more conductive than the capping layer 236 and the work function layer 234. In some instances, the metal cap layer 244 may include tungsten (W), cobalt (Co), nickel (Ni), molybdenum (Mo), or ruthenium (Ru). The metal cap layer 244 may be selectively deposited on electrically conductive surfaces using ALD, plasma-enhanced ALD (PEALD), metal organic CVD (MOCVD), or a suitable deposition process. In one embodiment, the metal cap layer 244 may include tungsten (W). The formation of the metal cap layer 244 reduces the gate contact resistance.

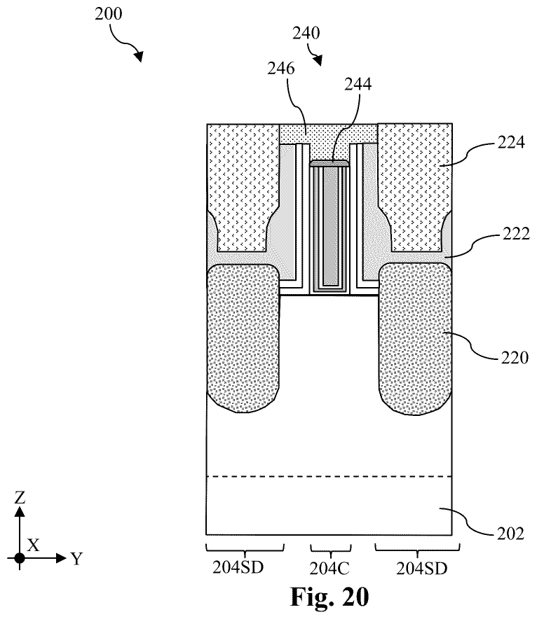

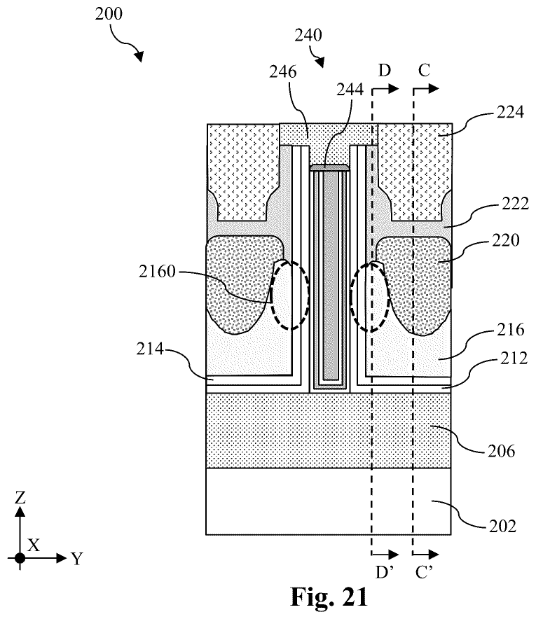

Referring to FIGS. 1 and 20-21, method 100 includes a block 126 where a self-aligned dielectric cap 246 over the metal cap layer 244. After the deposition of the metal cap layer 244, the dielectric capping layer 246 is blanketly deposited over the workpiece 200. The dielectric capping layer 246 may include silicon oxide, silicon nitride, silicon carbonitride, silicon oxycarbonitride, silicon oxycarbide, aluminum oxide, zirconium silicate (ZrSiO), hafnium silicate (HfSiO), hafnium oxide, or zirconium oxide and may be deposited using CVD or ALD. In one embodiment, the dielectric capping layer 246 includes silicon nitride. The dielectric capping layer 246 may also be referred to as a self-aligned contact (SAC) dielectric layer 246. After the deposition of the dielectric capping layer 246, the workpiece 200 is planarized using, for example, a CMP process, to provide a planar top surface as shown in FIGS. 20 and 21.

The DSW layer 216 that is not removed at block 116 plays an important role in reduction of parasitic capacitance. Reference is first made to FIG. 21. A portion of the gate structure 240 that is not directly over the channel region 204C is spaced apart from the source/drain features 220 by a leftover portion 2160 of the DSW layer 216. The parasitic capacitance between the gate structure 240 and one of the source/drain features 220 may be modeled as a parallel-plate capacitor. The leftover portion 2160 of the DSW layer 216 is disposed directly between the gate structure 240 and the source/drain feature 220 and directly impacts the effective capacitance of such modeling parallel-plate capacitor. Performance of a semiconductor device may be assessed using a ring oscillator (RO). According to experiments and computer simulations, the RO performance of the semiconductor structure 200 may be improved by about 0.7% to about 2.2% by reducing a dielectric constant of the DSW layer 216 by about 10%.

FIG. 22 illustrates a fragmentary cross-sectional view along line C-C′ in FIG. 21. Line C-C′ cuts across one of the source/drain features 220. As shown in FIG. 22, faceted growth of the source/drain feature 220 extends not only along the Z direction but also along the X direction. As a result, a portion of the source/drain feature 220 extends beyond sidewalls of the fin structure 204 to overhang the isolation feature 206. The CESL 222 extends substantially conformally along surfaces of the source/drain feature 220 and the ILD layer 224 fills the space and void left behind by the CESL 222. A portion of the DSW layer 216 is vertically spaced apart from a top surface of the isolation feature 206 by the first gate spacer layer 212 and the second gate spacer layer 214.

FIG. 23 illustrates a fragmentary cross-sectional view along line D-D′ in FIG. 21. Line D-D′ cuts through the left over DSW layer 216 disposed between the source/drain feature 220 and the second gate spacer layer 214 extending along a sidewall of the gate structure 240. As shown in FIG. 23, the lateral overgrowth portion of the source/drain feature 220 is spaced apart from the gate structure 240 (out of line and shown in dotted lines) along the Y direction by the CESL 222 and the leftover portion 2160 of the DSW layer 216. While CESL 222 also has an impact on the parasitic capacitance between the gate structure 240 and the source/drain feature 220, its dielectric constant may not be decreased as much as DSW layer 216 without other arrangements. For example, when the CESL 222 has a smaller dielectric constant, the formation of the source/drain contact opening may laterally breach the CESL 222 and cause electrical shorting.

Thus, in one embodiment, a semiconductor structure is provided. The semiconductor structure includes a fin structure arising from a substrate and extending lengthwise along a direction, an isolation feature disposed over the substrate and around the fin structure, a gate structure wrapping over a channel region of the fin structure and disposed on the isolation feature, a first gate spacer extending along a sidewall of the gate structure and a top surface of the isolation feature, a second gate spacer disposed over the first gate spacer, a filler dielectric layer disposed over the second gate spacer, an epitaxial feature disposed over a source/drain region of the fin structure, a portion of the epitaxial feature being disposed over the filler dielectric layer, an contact etch stop layer (CESL) disposed over the epitaxial feature and the filler dielectric layer, and an interlayer dielectric (ILD) layer disposed over the CESL. A portion of the CESL extends between the epitaxial feature and a sidewall of gate structure along the direction.

In some embodiments, a portion of the filler dielectric layer is disposed between the epitaxial feature and the sidewall of the gate structure along the direction. In some implementations, a composition of the first gate spacer is different from the second gate spacer or a composition of the filler dielectric layer and the composition of the second gate spacer is different from the composition of the filler dielectric layer. In some implementations, a dielectric constant of the filler dielectric layer is greater than a dielectric constant of the first gate spacer and the dielectric constant of the first gate spacer is greater than a dielectric constant of the second gate spacer. In some instances, the first gate spacer includes silicon oxycarbonitride or silicon oxycarbide and the filler dielectric layer comprise silicon oxynitride. The second gate spacer includes silicon oxide or silicon oxycarbide and an oxygen content of the second gate spacer layer is greater than an oxygen content of the first gate spacer. In some instances, a top surface of the epitaxial feature is higher than a top surface of the filler dielectric layer. In some instances, top surfaces of the first gate spacer and the second gate spacer are higher than a top surface of the filler dielectric layer. In some embodiments, the first gate spacer has a first thickness, the second gate spacer has a second thickness, and the filler dielectric layer has a third thickness greater than the first thickness or the second thickness.

In another embodiment, a semiconductor structure is provided. The semiconductor structure includes a substrate, a fin structure arising from the substrate and extending lengthwise along a direction, an isolation feature disposed over the substrate and around the fin structure, a gate structure wrapping over a channel region of the fin structure and disposed on the isolation feature, a first gate spacer extending along a sidewall of the gate structure and a top surface of the isolation feature, and an epitaxial feature disposed over a source/drain region of the fin structure, the epitaxial feature including a first portion and a second portion overhanging the isolation feature. Along the direction, the first portion and the second portion are spaced apart from the gate structure by a filler dielectric layer and a contact etch stop layer (CESL). The CESL is disposed over the filler dielectric layer. The filler dielectric layer includes silicon oxynitride and has a dielectric constant between about 5 and about 6.4 and the CESL includes silicon nitride and has a dielectric constant between about 6.4 and about 7.

In some embodiments, the filler dielectric layer is spaced apart from sidewalls of the source/drain region of the fin structure and the isolation feature by a first gate spacer and a second gate spacer. In some embodiments, a thickness of the filler dielectric layer is greater than a thickness of the first gate spacer or a thickness of the second gate spacer. In some embodiments, a dielectric constant of the filler dielectric layer is smaller than a dielectric constant of the CESL. In some embodiments, the filler dielectric layer includes silicon oxynitride and the CESL comprises silicon nitride.

In yet another embodiment, a method is provided. The method includes forming a fin structure on a substrate, the fin structure including a channel region and a source/drain region adjacent the channel region, forming an isolation feature over the substrate and around the fin structure, forming a dummy gate stack over the channel region of the fin structure, depositing a first gate spacer layer and a second gate spacer layer over the substrate, including over the dummy gate stack and the fin structure, depositing a filler dielectric layer over the second gate spacer layer, after the depositing of the filler dielectric layer, anisotropically etching the fin structure to form a source/drain recess over the source/drain region, epitaxially grown a source/drain feature over the source/drain recess, isotropically etching back the filler dielectric layer, and after the isotropically etching back, depositing a contact etch stop layer (CESL) over the source/drain feature and the filler dielectric layer.

In some embodiments, the isotropically etching back includes forming a recess between the source/drain feature and the second gate spacer extending along a sidewall of the dummy gate stack. In some implementations, the depositing of the CESL includes depositing the CESL into the recess. In some instances, the depositing of the filler dielectric layer includes conformally depositing the filler dielectric layer over the second gate spacer layer. In some instances, the isotropically etching back includes use of a phosphoric acid solution at a temperature between about 140° C. and about 180° C. In some embodiments, the first gate spacer includes silicon oxycarbonitride or silicon oxycarbide and the second gate spacer includes silicon oxide or silicon oxycarbide. In some implementations, the filler dielectric layer includes silicon oxynitride.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a fin structure arising from a substrate and extending lengthwise along a direction;
an isolation feature disposed over the substrate and around the fin structure;
a gate structure wrapping over a channel region of the fin structure and disposed on the isolation feature;
a first gate spacer extending along a sidewall of the gate structure and a top surface of the isolation feature;
a second gate spacer disposed over the first gate spacer;
a filler dielectric layer disposed over the second gate spacer;
an epitaxial feature disposed over a source/drain region of the fin structure, a portion of the epitaxial feature being disposed over the filler dielectric layer;
an contact etch stop layer (CESL) disposed over the epitaxial feature and the filler dielectric layer; and
an interlayer dielectric (ILD) layer disposed over the CESL,
wherein a portion of the CESL extends between the epitaxial feature and a sidewall of gate structure along the direction.

2. The semiconductor structure of claim 1, wherein a portion of the filler dielectric layer is disposed between the epitaxial feature and the sidewall of the gate structure along the direction.

3. The semiconductor structure of claim 1,
wherein a composition of the first gate spacer is different from the second gate spacer or a composition of the filler dielectric layer,
wherein the composition of the second gate spacer is different from the composition of the filler dielectric layer.

4. The semiconductor structure of claim 1,
wherein a dielectric constant of the filler dielectric layer is greater than a dielectric constant of the first gate spacer,
wherein the dielectric constant of the first gate spacer is greater than a dielectric constant of the second gate spacer.

5. The semiconductor structure of claim 1,
wherein the first gate spacer comprises silicon oxycarbonitride or silicon oxycarbide,
and the filler dielectric layer comprise silicon oxynitride,
wherein the second gate spacer comprises silicon oxide or silicon oxycarbide
wherein an oxygen content of the second gate spacer layer is greater than an oxygen content of the first gate spacer.

6. The semiconductor structure of claim 1, wherein a top surface of the epitaxial feature is higher than a top surface of the filler dielectric layer.

7. The semiconductor structure of claim 1, wherein top surfaces of the first gate spacer and the second gate spacer are higher than a top surface of the filler dielectric layer.

8. The semiconductor structure of claim 1,
wherein the first gate spacer comprises a first thickness,
wherein the second gate spacer comprises a second thickness,
wherein the filler dielectric layer comprises a third thickness greater than the first thickness or the second thickness.

9. A semiconductor structure, comprising:
a substrate;
a fin structure arising from the substrate and extending lengthwise along a direction;
an isolation feature disposed over the substrate and around the fin structure;
a gate structure wrapping over a channel region of the fin structure and disposed on the isolation feature;
a first gate spacer extending along a sidewall of the gate structure and a top surface of the isolation feature; and
an epitaxial feature disposed over a source/drain region of the fin structure, the epitaxial feature comprising a first portion and a second portion overhanging the isolation feature,
wherein, along the direction, the first portion and the second portion are spaced apart from the gate structure by a filler dielectric layer and a contact etch stop layer (CESL),
wherein the CESL is disposed over the filler dielectric layer,
wherein the filler dielectric layer comprises silicon oxynitride and has a dielectric constant between about 5 and about 6.4,
wherein the CESL comprises silicon nitride and has a dielectric constant between about 6.4 and about 7.

10. The structure of claim 9, wherein the filler dielectric layer is spaced apart from sidewalls of the source/drain region of the fin structure and the isolation feature by a first gate spacer and a second gate spacer.

11. The structure of claim 10, wherein a thickness of the filler dielectric layer is greater than a thickness of the first gate spacer or a thickness of the second gate spacer.

12. The structure of claim 9, wherein a dielectric constant of the filler dielectric layer is smaller than a dielectric constant of the CESL.

13. The structure of claim 9, wherein the filler dielectric layer comprises silicon oxynitride and the CESL comprises silicon nitride.

14. A method, comprising:
forming a fin structure on a substrate, the fin structure comprising a channel region and a source/drain region adjacent the channel region;
forming an isolation feature over the substrate and around the fin structure;
forming a dummy gate stack over the channel region of the fin structure;
depositing a first gate spacer layer and a second gate spacer layer over the substrate, including over the dummy gate stack and the fin structure;
depositing a filler dielectric layer over the second gate spacer layer;
after the depositing of the filler dielectric layer, anisotropically etching the fin structure to form a source/drain recess over the source/drain region;
epitaxially grown a source/drain feature over the source/drain recess;
isotropically etching back the filler dielectric layer; and
after the isotropically etching back, depositing a contact etch stop layer (CESL) over the source/drain feature and the filler dielectric layer.

15. The method of claim 14, wherein the isotropically etching back comprises forming a recess between the source/drain feature and the second gate spacer extending along a sidewall of the dummy gate stack.

16. The method of claim 15, wherein the depositing of the CESL comprises depositing the CESL into the recess.

17. The method of claim 14, wherein the depositing of the filler dielectric layer comprises conformally depositing the filler dielectric layer over the second gate spacer layer.

18. The method of claim 14, wherein the isotropically etching back comprises use of a phosphoric acid solution at a temperature between about 140° C. and about 180° C.

19. The method of claim 14,
wherein the first gate spacer comprises silicon oxycarbonitride or silicon oxycarbide,
wherein the second gate spacer comprises silicon oxide or silicon oxycarbide.

20. The method of claim 14. wherein the filler dielectric layer comprises silicon oxynitride.
